(19) United States
(12) Patent Application Publication
(10) Pub. No.: US 2008/0252407 A1
(43) Pub. Date: Oct. 16, 2008

(54) Multi-Layer Inductive Element for Integrated Circuit

(75) Inventor: Alma Anderson, Chandler, AZ (US)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/088,730

(22) PCT Filed: Oct. 4, 2006
(86) PCT No.: PCT/IB06/53635

§ 371 Date: Mar. 31, 2008

Related U.S. Application Data
(60) Provisional application No. 60/724,246, filed on Oct. 5, 2005.

(51) Int. Cl. H01F 17/00; H01L 21/02; H01F 41/04

(52) U.S. Cl. 336/177; 438/3; 29/602.1; 257/E21.022

(57) ABSTRACT

According to one example embodiment, an inductive element is used for power-conversion applications. The inductive element includes a substrate (188) having a first metal layer (190) on the substrate having a thickness greater than one micrometer and arranged as a first set of adjacent non-intersecting conducting segments. There is a ferromagnetic-based body (192) located on the first metal layer that has a ferromagnetic inner core area. At least one other metal layer (198) is on the ferromagnetic-based body and arranged as a second set of adjacent non-intersecting conducting segments. A plurality of conductive vias (194) are located in the ferromagnetic-based body and are arranged to connect respective ones of the first set of adjacent non-intersecting conducting segments to respective ones of the second set of adjacent non-intersecting conducting segments therein providing a contiguous conductive wrap around the inner core area. Other example embodiments include layer thicknesses in excess of those used in normal semiconductor processing.

The present invention is directed generally to inductive electrical devices and methodologies for manufacturing such devices for use in power conversion applications.

Inductors are typically coils of wire wound on an iron-based or ferromagnetic core. Most high value inductors use a ferrite core to reduce size. Due to the labor-intensive nature of the wound wire to form an inductor and/or their required circuit-board real estate, inductors tend to be expensive compared to other components in electronics. Despite their expense, inductors play a critical role for many applications, especially in high-frequency applications and in applications for coupling power.

Inductive components are commonly fabricated using ferromagnetic cores and windings of insulated electrical wire. The ferromagnetic cores are typically toroidal cores, rod cores, or assemblies made of an “E” shaped ferromagnetic part and a ferromagnetic cap connecting the three legs of the E.

The toroid and rod cores are manually or automatically wound with the insulated copper wire to form a number of multiple turn windings for a transformer or a single winding for an inductor. The assembly is then encapsulated to protect the wires. The circuit connection is made by the solder termination of the wires as required by the application. This approach has high labor costs due to individual pad handling. It also has large variability in electronic parameters such as leakage inductance, distributed and inter-winding capacitance, and common mode imbalance between windings because of the difficulty in exact placement of the copper wires.

The “E” shaped and encompassing cap assembly is made into an inductive component by manually or automatically winding copper insulated wires around the legs of the E as required. Either gluing or clamping the cap in place and final encapsulation completes this subassembly. Similarly, the circuit connection is made by means of solder termination of the wires as required by the application. Not only does this device have the limitations of the toroid and rod core, as mentioned above, but also it generally is a much larger device. Because the cap is a separate device the magnetic paths have a resistance of non-ferromagnetic gaps between the E and the cap reducing the efficiency of the transformer.

In recent years inductors have been incorporated into semiconductor manufacturing processes for high-frequency IC applications such as used in cellular-telephone chips. For example, integrated inductors have been made using thin-film processing to make a flat-spiral coil of conductor as the “wire.” Inductors with inductance values of a few nanohenries, which are sufficient for RF applications, can be realized using this flat-spiral approach. Spiral inductors fabricated by PC board processing methods have also been incorporated into PC boards, again, for RF type applications where only relatively small inductance values are needed.

For power-directed applications, inductors store energy in their magnetic field and are therefore useful in converting power from one voltage to another such as in boost regulators and in Buck regulators where the energy efficiencies are much higher than with linear regulators. In these power-conversion applications, the inductors used in RF applications are inadequate. Rather than requiring only a few nanohenries of inductance, for a typical power-conversion application, inductors often require frequencies in the high kiloHertz (kHz) to low megaHertz (MHz) range, which translates to inductance values of one or more microhenries.

In an exemplary LED current-driving application, sufficient voltage is needed to pass the necessary current for driving the device, and the magnitude of the current determines the brightness. Historically resistors were used to limit the current and drop the voltage difference between the LED's turn-on voltage and the power supply voltage. The resistor accomplished its task by converting the excess voltage times the current into heat. By using an inductor and a switching transistor, the same average current can be applied to the LED and only a small amount of energy is wasted. Further, the circuit can be configured such that a voltage less than the LED's turn-on voltage can be used to supply the energy for the LED. These circuit techniques exist in the prior art using wire wound inductors.

Various approaches have been used to implement inductors. For example, PCT Publication No. WO0225797 A2, discloses an inductor manufacturing process using a core material arranged between two PC board layers (or two flex layers), with the inductor being an integral part of the fabrication of PCB's or FLEX's, with a ferrite or high permeability core laminated between layers on which the “wires” are patterned. Another example approach as described in U.S. Pat. No. 5,336,921, concerns trench-based inductors using semiconductor processing dimensions on the order of one micrometer and providing inductors with relatively small inductance values. In U.S. Pat. No. 5,801,100, an inductor fabrication approach is discussed that uses a copper conductor on a nickel film to provide inductors also with relatively small inductance values; the approach includes process dimensions on the order of one micrometer and using a core material with thickness on the order of one micrometer. U.S. Pat. No. 6,166,422 describes an inductor having a cobalt/nickel metal core useful with wafer processing and also providing inductance values that are not suitable for power conversion.

In connection with the present invention, it has been recognized that many electrical applications would be advantaged by incorporating less expensive, moderately-valued inductors. Applications including, but not limited to power conversion applications requiring DC-to-DC conversion and/or those controlling Light Emitting Diodes (LEDs), would be especially benefited using inductors with inductance values on the order of a microhenry or so.

Certain aspects of the present invention are directed to inexpensive moderate-value inductors that can be either incorporated into a semiconductor package or formed as part of a semiconductor manufacturing process to be implemented in power-conversion applications or in LED current-driving applications.

Another aspect of the present invention includes a set of semiconductor processing steps for manufacturing a large number of inductors on a common substrate such as large numbers of integrated circuits (ICs) on a single wafer. The substrate can be either an insulating material such as glass or the surface of a wafer on which ICs have already been processed. The inductors, rather than being flat spirals of conductor are three dimensional structures of conductive material effectively wrapped around a ferrite core by being lithographically patterned into conductive lines connected by conductive vias to encircle the ferrite core.

One example embodiment of the present invention is directed to an inductive element for use in power conversion. The inductive element includes a substrate having an insulating surface with a first metal layer on the substrate and arranged as a first set of adjacent non-intersecting conducting segments. There is a ferromagnetic-based body located on the first metal layer that has a ferromagnetic inner core area. At least one other metal layer is formed on the ferromagnetic-based body and arranged as a second set of adjacent non-intersecting conducting segments. A plurality of conductive vias are located in the ferromagnetic-based body and are arranged to connect respective ones of the first set of adjacent non-intersecting conducting segments to respective ones of the second set of adjacent non-intersecting conducting segments to form a contiguous conductive wrap around the inner core area.

Another example embodiment is directed to a method for forming an inductive element on an IC substrate for use in power conversion. The method includes forming a first layer on the substrate as a first set of adjacent non-intersecting conducting segments and depositing a ferromagnetic-based body having a ferromagnetic inner core area on the first layer. Next, a plurality of vias are etched through the ferromagnetic-based body to access the first layer. The vias are filled with conductive material to contact respective ones of the first set of adjacent non-intersecting conducting segments. Then at least one other layer is formed on the ferromagnetic-based body as a second set of adjacent non-intersecting conducting segments so that the plurality of filled vias connect respective ones of the first set of adjacent non-intersecting conducting segments to respective ones of the second set of adjacent non-intersecting conducting segments to form a contiguous conductive wrap around the inner core area.

The above summary of the present invention is not intended to describe each illustrated embodiment or every implementation of the present invention. The figures and detailed description that follow more particularly exemplify these embodiments.

The invention may be more completely understood in consideration of the following detailed description of various embodiments of the invention in connection with the accompanying drawings, in which:

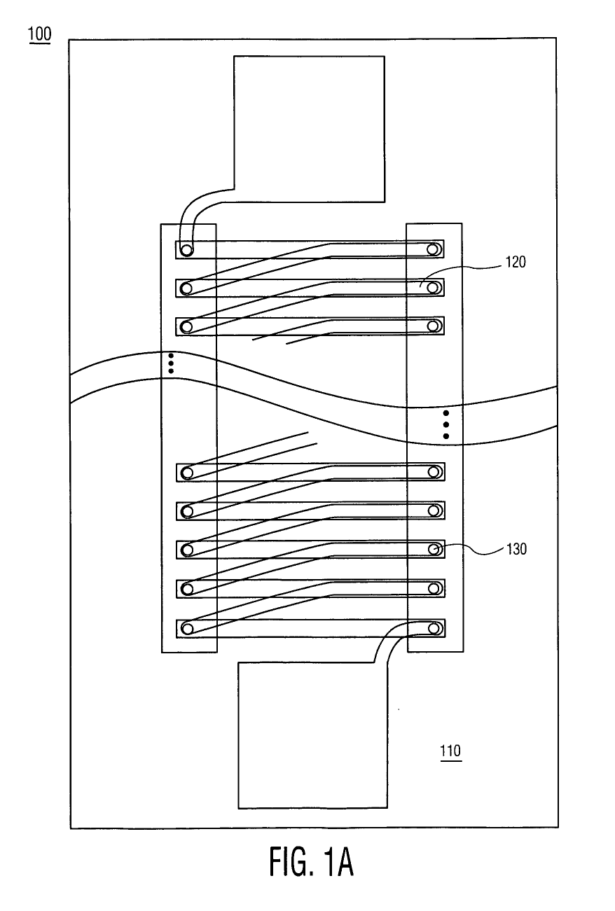

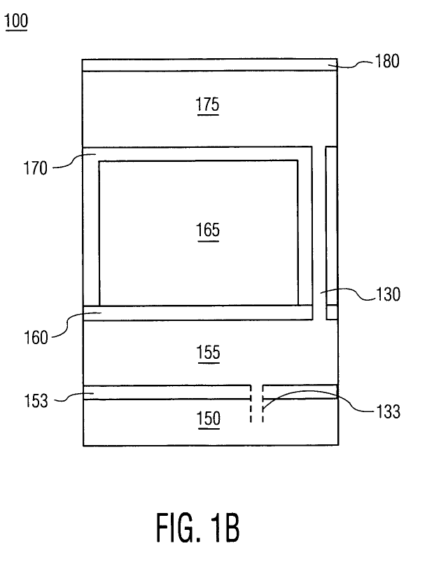

FIG. 1A is a top-down view of an inductive element, according to an example embodiment of the present invention;

FIG. 1B is a cross-sectional view of an inductive element, according to an example embodiment of the present invention;

FIG. 1C is a layer-by-layer view of an inductive element, according to an example embodiment of the present invention; and

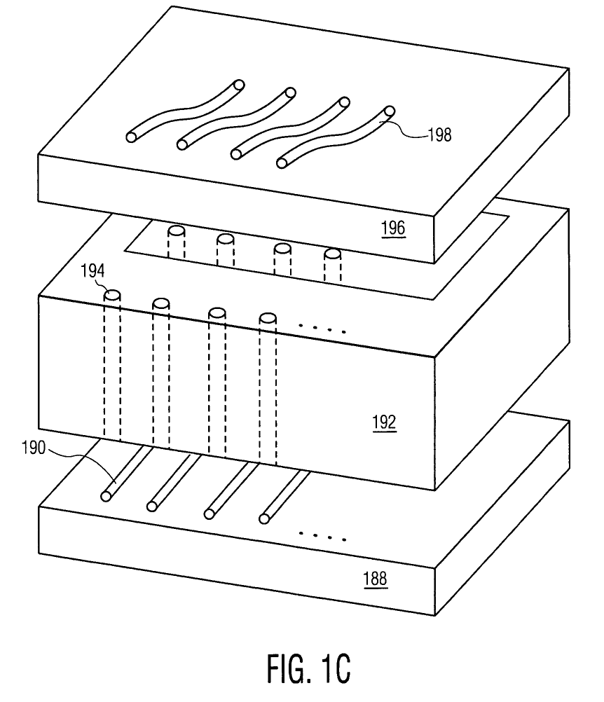

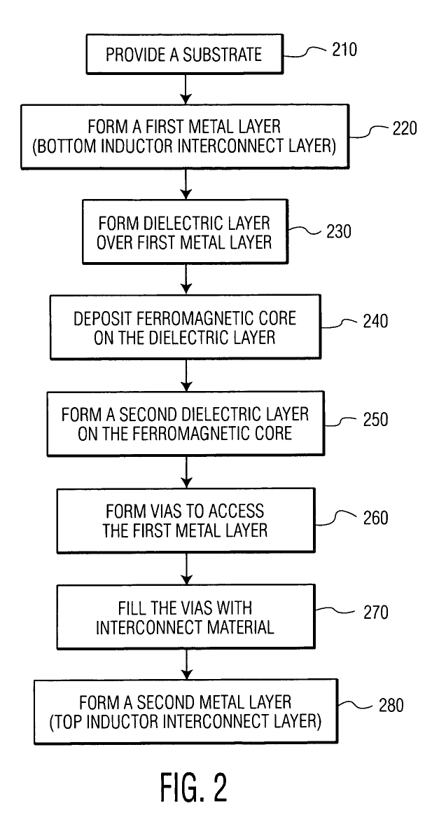

FIG. 2 illustrates a process for forming an inductive element, according to an example embodiment of the present invention.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the scope of the invention as defined by the appended claims.

The present invention is believed to be applicable to inductive elements and methods of forming inductive elements to be used in power conversion applications.

An example embodiment is directed to an inductive element for use in power conversion. The inductive element includes a substrate with a first metal layer formed on the substrate and arranged as a first set of adjacent non-intersecting conducting segments. There is a ferromagnetic-based body located on the first metal layer that has a ferromagnetic inner core area. At least one other metal layer is formed on the ferromagnetic-based body and arranged as a second set of adjacent non-intersecting conducting segments. A plurality of conductive vias are located in the ferromagnetic-based body and are arranged to connect respective ones of the first set of adjacent non-intersecting conducting segments to respective ones of the second set of adjacent non-intersecting conducting segments to form a contiguous conductive wrap around the inner core area.

FIG. 1A illustrates a top-down view of an inductive element, consistent with the above embodiment and also according to the present invention. The inductive element 100 includes a closed E-shaped ferromagnetic core 110 and a plurality of conductive segments 120 connected by vias 130 to effectively form a conductive coil around the center portion of the ferromagnetic core 110. The vias 130 connect a top layer of conductive segments with a bottom layer of conductive segments through dielectric or insulating material. The different layers of the inductive element may be better understood with the following views of FIGS. 1B and 1C.

FIG. 1B is a cross-sectional view of an inductive element, according to an example embodiment. As is shown, the inductive element is made of several layers. At the bottom of the device, a substrate 150 is located. The surface of the substrate 150 is covered by an insulating layer 153. Above the substrate 150 (and insulating layer 153) is a first conductive layer 155 that is patterned into a plurality of non-intersecting segments. A second insulating layer 160 protects the first conductive layer 155 from the ferromagnetic core 165 located above the insulating layer 160. A third insulating layer 170 encapsulates the exposed portions of the ferromagnetic core 165. A second conductive layer 175 is located above the third insulating layer 170. The second conductive layer 175 can also be used to fill in vias 130 that are located in the third insulating layer 170, thereby conductively connecting the first 155 and second 175 conductive layers. Alternatively, another via 133 can be located in the first insulating layer 153 and substrate 150 to connect conductors in the substrate 150 with conductors in the first conductive layer 155. The top of the device is protected by another, in this case, fourth insulating layer 180.

FIG. 1C illustrates how the above-discussed layers are aligned to effectively form a contiguous wire coil around a portion of a toroid-shaped ferromagnetic core in another, layer-by-layer, view of an inductive element according to an example embodiment. As is shown in the bottom portion of the device 188, the first conductive layer is patterned into a plurality of non-intersecting segments 190. The middle portion of the device 192 includes a ferromagnetic-based body that includes a ferromagnetic core and insulating dielectric. In portions of the insulating dielectric, vias 194 are formed to align with and provide access to the plurality of non-intersecting segments 190 of the first conductive layer. The vias 194 are filled with conductive material to electrically connect with the non-intersecting segments 190 of the first conductive layer and effectively form the side portion of the conductive winding. In the top portion of the device 196, a second conductive layer is patterned into a second set of non-intersecting segments 198 and aligned with the vias 194 to complete the conductive coil around the ferromagnetic core.

For power conversion uses, an inductor needs to have low winding resistance as well as high inductance. The winding resistance can be optimized by the use of large cross-section wires, which in semiconductor processing translates into thick, wide, low resistance metal traces. Typical semiconductor processing uses thin and narrow lines and spaces to achieve “fine pitch” high density interconnect. Copper interconnect has become popular even in fine pitch interconnect because low resistance is important. The inductor also needs a large core cross-section, which translates to vertical height separation between the lower interconnect layer and the upper interconnect layer used to form the windings. The ideal core cross-section would be square because for windings that are formed with photolithographic processing, a square is the closest replication of the round shape that minimizes winding wire length. The square shaped core minimizes both the winding length for a given number of turns and the inductor foot print on the substrate.

Scaling inductors aggravate parasitic capacitance because the cross-sectional area of the core and the core's permeability are linearly related to inductance. Decreasing the cross-section of the same core material reduces the inductance, thus requiring more turns. Reducing the conductive wire's width and/or thickness increases the coil resistance and reduces the current carrying ability. Therefore, while a smaller inductor can have the same inductance as a larger one it will have a lower current limit. Reducing the space between the wire windings increases the capacitance between the windings in the coil.

Since current is always the primary objective in power-conversion applications, the conductive wire cross-section is important as the minimum wire cross-section for a given current has an absolute minimum determined by electromigration of the conductor. The parasitic resistance however defines a practical limit well above the electromigration limit where the resistive energy loss/resistive heating of the conductor becomes excessive. The resistance limited minimum cross-section of a conductor in an inductor is well above the process limited minimum metal width. Thus, the higher the operating frequency, the higher the losses due to parasitic capacitance are, and the practical conductor spacing for an inductor is well above the process limited minimum metal to metal spacing.

Since inductance increases linearly with respect to cross-sectional area, a flat spiral inductor would need to be a thousand times larger, which is prohibitive in an integrated circuit. Typically, circuitry is not placed under a spiral inductor because the magnetic field is concentrated in the middle of the coil. This magnetic field could interact with the circuit below. The bulk silicon below a flat spiral inductor is also known to cause Eddie current losses that waste energy and degrade the effectiveness of the inductor. By making the axis of the inductor parallel to the substrate surface, rather than vertical to the substrate surface, the high-intensity changing magnetic field resides above the surface of the substrate. Additional windings have the same cross-section as the first so the inductor resembles a solenoid and the inductance increases with the square of the number of windings. By using a high magnetic permeability core such as a ferrite core the magnetic fields can be further concentrated, and if a closed shape like a toroid is used for the core, most of the magnetic field will be concentrated in the plane of the toroid. This will have little effect on the substrate below making it practical to use the area below the inductor for active circuitry.

Although integrated inductors can use at least some of the same processing equipment and processes as normal wafer processing the need for large feature sizes and thick films is in direct opposition to standard wafer processing. Therefore, a mix of standard wafer processing and nonstandard wafer processing are used to optimize the processing and minimize the cost of the inductor.

FIG. 2 is a flow diagram of an example process for making an inductive element according to one embodiment of the present invention. In an example embodiment, the device is built on a substrate 210. A first conductive, e.g., metal, layer is formed 220 on the substrate and patterned into a plurality of non-intersecting segments. In order to protect the device insulating dielectric layers are interspersed throughout the processing. So, a first dielectric layer is formed 230 on the first metal layer. Next, a ferromagnetic body is deposited 240 on the first dielectric layer. The ferromagnetic body can be patterned into a closed shape such as a toroid or capped-E shape, as discussed above. A second dielectric layer is formed 250 to encapsulate the ferromagnetic body. Vias are then etched 260 through the second dielectric layer to access the first metal layer. The vias are filled 270 with conductive material to electrically connect to the first metal layer. A second metal layer is formed 280 and patterned into a second set of non-intersecting segments to electrically connect two vias and complete the conductive coil. Alternatively the formation of the second metal layer may also include filling the vias with the same material.

Consistent with the above described embodiment and according to another, more specific implementation of the present invention, the following discussion uses semiconductor processing techniques to form an inductor. As it should be apparent from this discussion, conventional deposition, patterning, and etching techniques can be used, except where otherwise indicated. Starting from an insulating substrate surface on a processed semiconductor wafer or other substrate, a first level of inductor interconnect is formed and patterned. This interconnect may be a variety of workable conductive materials including, but not limited to copper (with a barrier if a semiconductor wafer is used), aluminum and aluminum alloys, copper alloys, and gold.

The first inductor interconnect layer can be patterned by either thick-film or thin-film methods. Thick-film processing is essentially a mechanical printing process such as inkjet or silk-screen deposition to selectively deposit the “ink” followed by a process step to convert the “ink” into the desired material. Thin-film processing includes depositing a blanket coating of the desired material followed by patterning. Thin-film patterning techniques include wet etch, dry etch, chemical mechanical polish (CMP), electro chemical mechanical polish (ECMP) and lift off.

In the wet and dry etch cases a photo resist layer is deposited after the thin-film layer is deposited and photo lithographical techniques are used to pattern the photo resist which defines the pattern of the interconnect layer. Then the photo resist pattern is used to protect the interconnect during etching to remove the unwanted material. The photo resist can be applied directly to the interconnect material or to a surface layer on the interconnect that promotes adhesion, minimizes reflections and/or is used as a “hard mask” that replaces the photo resist during the etch process.

In the cases of CMP, ECMP, and lift off, before the deposition of the interconnect layer the photo patterning is done. For CMP and ECMP a trench pattern is etched in the insulating layer in the shape of the intended conductor and then the conductor is deposited and a polishing technique is used to remove the excess material. In the case of lift off processing, the conductor is deposited on the substrate and a photo resist pattern at the same time in such a way that the interconnect on the substrate is not connected to the material on top of the photo resist so that the unwanted material falls off or “lifts off” when the photo resist is removed.

Next an insulating layer is applied over the patterned first interconnect to isolate the interconnect lines and provide the surface for the ferrite core. The insulating layer must provide sufficient isolation for the interconnect and chemical barrier, as well as mechanical support for the ferrite core. The insulating layer must also be etchable so that vias can be formed to access the first interconnect layer in a later processing step. The preferred insulating layer is silicon nitride, because of is well established barrier properties, although silicon dioxide or other materials or combinations of materials or stacked layers of materials may also be used. The insulating layer may be deposited in any number of ways so long as the deposition and curing process (if needed) temperature do not compromise the underlying interconnect layer or substrate. Such deposition methods include chemical vapor deposition, plasma enhanced chemical vapor deposition, RF sputtering, reactive sputtering, spin on, and silk-screen deposition. Generally spin on and silk-screen deposition methods require some sort of cure to produce acceptable films.

Using any of a variety of methods, a ferrite core is formed over the insulating layer. The ferrite core is a ferromagneticly-based material that includes iron and can also include materials such as magnesium and/or oxygen. The thickness and the width of the ferrite core largely determines the cross section of the coil of the inductor. For the same layout area the thickness of the ferrite core can be used to increase or decrease the inductance by increasing or reducing the thickness respectively. In a more specific embodiment, the ferrite core is deposited using a silk-screening approach. Silk-screening permits the deposition of thick layers without an etching process to pattern the material. This approach takes advantage of processing methods not normally used on wafers to do a thick film printing process. One advantage is the simplicity of core formation. However, this approach hinders patterning the top layer of interconnect due to the height difference which causes problems with photoresist deposition and exposure.

After the ferrite core is formed, it is encased in an insulating layer. In the simplest process this would be a conformal silicon nitride film or some other insulating film. Alternatively the insulating film could be built up and planarized above the height of the ferrite core.

Next, vias are formed down to the first inductor interconnect layer and possibly on down to the underlying substrate in some cases. Care must be taken to avoid unwanted holes in the insulating layer over the ferrite core while producing the vias to the underlying interconnect layer. Further, since the vias may extend as much as 20-30 micrometers or more below the surface, care must be taken to make certain that the vias etch all the way down to the underlying interconnect.

Next the vias are filled and the second or top inductor interconnect layer is deposited. As with the first inductor interconnect layer copper is preferred for its low resistance but aluminum, or a number of other metals and alloys may be used. In the case of extreme depth requirements, it may be preferable to use larger vias (e.g., diameters of eight micrometers) and a deposition method that will fill the vias such as electro plating of copper, organometalic CVD or CVD. Sputtering may also be used but it tends to fail to completely fill deep vias. The steep sides of the ferrite core make it difficult to use PVD depositions like sputtering to achieve a uniform film thickness. Even though electro plating or CVD/organometalic CVD tend to result in the best uniformity, each of the methods can result in usable conductive films.

Patterning the interconnect can be achieved through the use of relaxed lithography rules.

To minimize the cost, a top insulator coating is optional, however for mechanical and handling reasons it is preferable to apply a final insulating protective film over the top interconnect. This insulating film is then patterned to open the bond pads so that the inductor can be connected.

It is also recognized that by adding two additional layers of interconnect, one before the first inductor interconnect layer and the other above the top inductor interconnect layer described above that it is possible to add another layer of windings around the core. This could be extended to yet more layers of windings at the added expense of two layers of interconnect, two insulating layers, and four masking steps per layer of windings.

Because the inductor is to be used in the same package as the IC if not physically manufactured on the IC substrate it is desirable to minimize the magnetic field that is coupled to the IC. By using closed shapes like toroids for the ferrite core material it is possible to confine much of the magnetic field to the core. So even though a slug or glob of ferrite material will increase the inductance of the coil, the preferred shapes are closed structures consisting of one or two loops.

It is also recognized that transformers may be made using these processing steps by creating two or more separate coils on a common ferrite core.

Since a square core needs to be on the order of 50-100 micrometers, or more, and normal semiconductor processing uses thin film layers that are most often less than 1 micrometer or possibly 2-3 micrometers, the topology difference between the inductor processing and standard semiconductor processing is significant. This difference in vertical height means that the processing will at best have to be modified from its standard semiconductor processing cousin or that it may need to be replaced. This, and the fact that the core material differs from materials normally used in semiconductor manufacturing, allows for a variety of processing techniques to be used.

Other implementations of the present invention are directed to variations of the above specific semiconductor processing techniques to form such an inductor. For example, another method for depositing the ferrite core is ink jet deposition using a liquid ink rather than the paste used for silk-screen deposition. The material deposited using thick-film methods needs to be cured to remove the solvents used to make the ink or paste printable.

Thick layers deposited and patterned by thin-film techniques may also prove workable with the development of a satisfactory etch and photo lithography process.

As yet another approach for forming the ferrite core employs an insulating film built up first to the height of the intended ferrite core and a damascene like process is used to embed the ferrite core in the insulating film, fallowed by a top film deposition.

A modified hard-mask approach can also be implemented. This approach is an extension of a process developed to handle topology problems, mostly depth of focus problems before CMP became popular. This approach was used to overcome topology problems cause by poly gate and/or metal lines that provide wafer topology that does not disappear when conformal dielectric layers are added.

This topology also makes photoresist processing difficult because it results in non-uniform photo resist and depth of focus problems during exposure. However, these step heights were on the order of one micrometer when the process was developed. The solution was to spin on a non-photo active organic material that survives the processing conditions necessary to deposit a hard layer such as SiO2 or SiN. These layers are flat so that it is easy to pattern them with conventional photoresist processing. The etch of the SiO2 or SiN is selective so that the organic underlayer is essentially undamaged. Then an O2 reactive ion etch (RIE) process is used to transfer the pattern by selective etching down through the organic layer. The resulting stack is then used as the mask for subsequent processing. This conventional processing approach is modified by boosting the organic layer thickness by a factor of 100 and adding a subsequent hard liner to the sides' of the before deep trenches in the organic layer. The liner is formed the same way as a sidewall spacer except on a much larger scale, namely an additional hard layer is conformally deposited and a RIE etch of that layer is used to selectively remove the excess deposited material on the flat surfaces leaving the side walls unetched. This prevents the core material in the trench and the conductor material in the vias from reacting with the organic layer.

One advantage to this approach is that it maintains a relatively flat surface. Difficulties come from the sheer height requirements, trenches 50-100 micrometers deep and significant aspect ratios to the vias used to connect the lower interconnect layer to the upper interconnect layer. The via fill process must be low resistance and accommodate an aspect ratio of as much as 10 to 20, which is beyond what is normally seen in wafer processing.

While certain aspects of the present invention have been described with reference to several particular example embodiments, those skilled in the art will recognize that many changes may be made thereto without departing from the spirit and scope of the present invention. Aspects of the invention are set forth in the following claims.

1. An inductive element comprising:
a substrate; a first layer on the substrate having a thickness greater than one micrometer and arranged as a first set of adjacent non-intersecting conducting segments;
a ferromagnetic-based located on the first layer and having a ferromagnetic inner core area;
at least one other on the ferromagnetic-based body and arranged as a second set of adjacent non-intersecting conducting segments;
and a plurality of conductive vias in the ferromagnetic-based body arranged to connect respective ones of the first set of adjacent non-intersecting conducting segments to respective ones of the second set of adjacent non-intersecting conducting segments, therein providing a contiguous conductive wrap around the inner core area for use in power conversion.

2. The inductive element of claim 1, wherein the first layer includes metal and has a thickness of at least two micrometers.

3. The inductive element of claim 1, wherein the ferromagnetic inner core area is in the shape of a toroid.

4. The inductive element of claim 1, wherein the ferromagnetic inner core area is at least ten micrometers thick.

5. The inductive element of claim 1, wherein the ferromagnetic-based body includes an insulating layer covering the ferromagnetic inner core area.

6. The inductive element of claim 1, wherein the ferromagnetic core includes iron, magnesium, and oxygen.

7. The inductive element of claim 1, wherein each of the plurality of conductive vias has a diameter of at least 7 micrometers.

8. A method for forming an inductive element on an IC substrate, the method comprising:
forming a first layer on the substrate as a first set of adjacent non-intersecting conducting segments;
depositing a ferromagnetic-based body having a ferromagnetic inner core area on the first layer; etching a plurality of vias through the ferromagnetic-based body to access the first layer;
filling the plurality of vias with conductive material to contact respective ones of the first set of adjacent non-intersecting conducting segments;
and forming at least one other layer on the ferromagnetic-based body as a second set of adjacent non-intersecting conducting segments, where the plurality of filled vias connect respective ones of the first set of adjacent non-intersecting conducting segments to respective ones of the second set of adjacent non-intersecting conducting segments to form a contiguous conductive wrap around the inner core area for use in power conversion.

9. The method of claim 8, wherein depositing a ferromagnetic-based body having a ferromagnetic inner core area includes depositing an insulating layer over the ferromagnetic inner core area.

10. The method of claim 8, wherein depositing a ferromagnetic-based body having a ferromagnetic inner core area includes silk screening an ink base on the first layer.

11. The method of claim 8, wherein depositing a ferromagnetic-based body having a ferromagnetic inner core area includes depositing an organic layer and a hard mask.

12. The method of claim 8, wherein forming at least one other layer on the ferromagnetic-based body includes using photoresist for patterning.

13. The method of claim 8, wherein forming at least one other layer on the ferromagnetic-based body includes using a blanket etch.

14. The method of claim 10, wherein depositing an ink base via silk screening includes forming a ferromagnetic inner core area that is at least 10 micrometers thick.
